(19) United States
(12) Patent Application Publication
(10) Pub. No.: US 2008/0093643 A1
(43) Pub. Date: Apr. 24, 2008

(54) Non-volatile memory device and fabrication method

(76) Inventor: Sung-Chul Park, Dongjak-gu (KR)

Correspondence Address: VOLENTINE & WHITT PLLC, ONE FREEDOM SQUARE, 11951 FREEDOM DRIVE SUITE 1260, RESTON, VA, 20190, US

(21) Appl. No.: 11/642,924

(22) Filed: Dec. 21, 2006

(30) Foreign Application Priority Data
Oct. 23, 2006 (KR) 2006-103058

(51) Int. Cl. H01L 29/94; H01L 21/336

(52) U.S. Cl. 257/296; 438/264

(57) ABSTRACT

Provided is a non-volatile memory device capable of operating with two cells at each one unit. The memory cell unit includes a common source region on an active region, a select gate covering the common source region, a first memory gate on the active region adjacent to one side of the select gate, a second memory gate on the active region adjacent to the other side of the select gate.

This U.S. non-provisional patent application claims priority under 35 U.S.C. § 119 to Korean Patent Application No. 2006-103058, filed on Oct. 23, 2006, the subject matter of which is hereby incorporated by reference.

### BACKGROUND OF THE INVENTION

1. Field of the Invention

The present invention relates to a semiconductor device, and more particularly, to a non-volatile memory device and related method of fabrication.

2. Description of the Related Art

A non-volatile memory device is able to retain stored data without power being supplied to it. Non-volatile memory devices include mask ROM devices, erasable programmable read only memory (EPROM) devices, electrically erasable programmable read only memory (EEPROM) devices, and flash memory devices. Flash memory devices may be further classified as NOR flash memory devices and NAND flash memory devices.

FIG. (FIG.) 1A is a plan view of a conventional EEPROM. FIG. 1B is a related sectional view taken along line I-I′ of FIG. 1A, and FIG. 1C is an equivalent circuit diagram. Referring to FIGS. 1A, 1B, and 1C, the EEPROM includes an active region 12 defined by a device isolation layer 13 of a semiconductor substrate 11. A source region 12s, a drain region 12d, and a floating diffusion region 12f are provided on the active region 12. A word line WL crosses over the active region 12. A select line SL apart from the word line WL crosses over the active region 12 in parallel with the word line WL. A bit line BL is connected to the drain region 12d through a bit line contact plug 31. A floating gate electrode 21, a gate interlayer dielectric layer 23, and a control gate electrode 25 are provided on the active region 12 between the drain region 12d and the floating diffusion region 12f. A gate insulation layer 15 is interposed between the floating gate electrode 21 and the active region 12. The control gate electrode 25 is connected to the word line WL. The floating diffusion region 12f may extend toward the active region 12 below the word line WL.

A constituent memory transistor MT includes the word line WL, the drain region 12d, and the floating diffusion region 12f. A select gate electrode 27 is provided on the active region 12 between the floating diffusion region 12f and the source region 12s. A select gate insulation layer 17 is interposed between the select gate electrode 27 and the active region 12. The select gate electrode 27 is connected to the select line SL. A constituent select transistor ST includes the select line SL, the floating diffusion region 12f and the source region 12s. The select transistor ST may have a conventional MOS transistor structure.

Since the programming and erase operations applied to the conventional EEPROM make use of the so-called Fouler-Nodheim (F-N) tunneling effect, their performance endurance (i.e., their ability to be repeatedly programmed and erased) is excellent. However, since each single bit memory cell unit of the conventional EEPROM includes two transistors, one select transistor ST and one memory transistor MT, it is very difficult to achieve higher integration densities.

On the other hand, since a memory cell unit of conventional NOR flash memory devices includes only a single transistor, significantly higher integration densities may be achieved, along with faster overall operating speeds. Unfortunately, the programming operation applied to NOR-type flash memory devices makes use of channel hot electron injection effects rather than F-N tunneling. As a result, the current required during NOR-type flash memory programming operations is relatively high and the endurance of its memory cells is relatively poor.

### SUMMARY OF THE INVENTION

In contrast, embodiments of the present invention provide a non-volatile memory device capable of achieving greater integration densities without the attendant disadvantages associated with NOR-type flash memory.

In one embodiment, the invention provides a non-volatile memory device comprising; a semiconductor substrate having a device isolation layer defining an active region, and memory cell units arranged on the semiconductor substrate in a matrix having rows and columns. Each of the memory cell units comprises; a common source region disposed in the active region, a select gate covering the common source region, a first memory gate on the active region adjacent to one side of the select gate, a second memory gate on the active region adjacent to the other side of the select gate, and first and second drain regions in the active region at both sides of a gate structure including the first memory gate, the second memory gate, and the select gate.

In another embodiment, the invention provides a method of forming a non-volatile memory device, the method comprising; providing a semiconductor substrate having a device isolation layer defining an active region, forming a select gate covering a common source region in the active region, forming first and second memory gates in the active region at both sides of the select gate, forming first and second drain regions in the active region at both sides of a gate structure including the first memory gate, the second memory gate, and the select gate, and forming a bit line connecting the first and second drain regions commonly.

### BRIEF DESCRIPTION OF THE DRAWINGS

FIG. 1A is a plan view of a conventional EEPROM;

FIG. 1B is a section view taken along line I-I′ of the EEPROM shown in FIG. 1A;

FIG. 1C is an equivalent circuit diagram of the EEPROM shown in FIG. 1A;

FIG. 2A is a plan view of a memory cell unit of a non-volatile memory device according to an embodiment of the present invention;

FIGS. 2B and 2C are a sectional view and an equivalent circuit diagram of the non-volatile memory device shown in FIG. 2A, respectively;

FIG. 3A is a plan view of a memory cell unit of a non-volatile memory device according to another embodiment of the present invention;

FIGS. 3B and 3C are a sectional view and an equivalent circuit diagram of the non-volatile memory device shown in FIG. 3A, respectively;

FIG. 4A is a layout of a non-volatile memory device array according to another embodiment of the present invention;

FIG. 4B is a layout of a non-volatile memory device array according to another embodiment of the present invention;

FIG. 5 is a view of an equivalent circuit diagram of a non-volatile memory device array according to embodiments of the present invention;

FIGS. 6A through 6D are views illustrating a method of driving a non-volatile memory device according to embodiments of the present invention;

FIGS. 7A and 7B are graphs of representative threshold voltages apparent in programming and erase operation applied to a non-volatile memory device according to embodiments of the present invention;

FIGS. 8A through 9A are plan views illustrating a method of forming a non-volatile memory device according to an embodiment of the present invention;

FIGS. 8B through 9B are sectional views related respectively to FIGS. 8A through 9A;

FIGS. 10A through 13A are plan views illustrating a method of forming a non-volatile memory device according to another embodiment of the present invention; and

FIGS. 10B through 13B are sectional views related respectively to of FIGS. 10A through 13A.

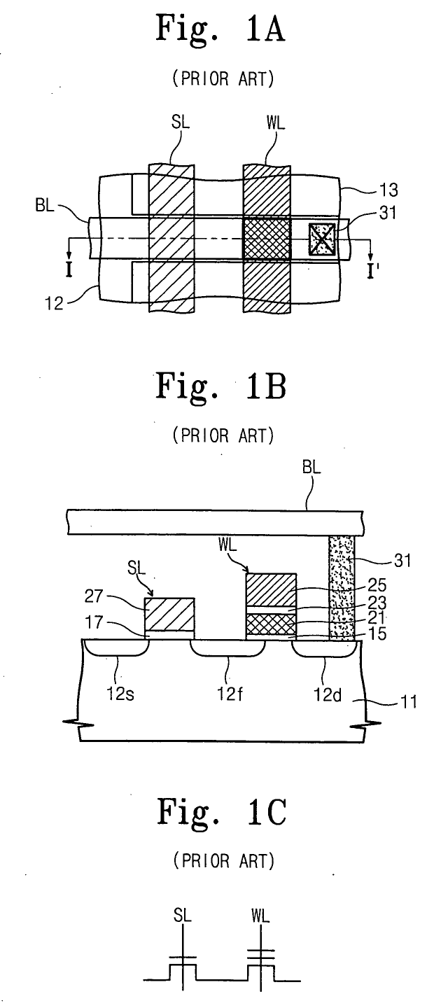

### DESCRIPTION OF EMBODIMENTS

Embodiments of the invention will now be described in some additional detail with reference to the accompanying drawings. The present invention may, however, be embodied in different forms and should not be constructed as being limited to only the embodiments set forth herein. Rather, these embodiments are presented as teaching examples.

Drawing dimensions for certain layers and regions may be exaggerated for clarity of illustration. It will also be understood that when a layer (or film) is referred to as being ‘on’ another layer or substrate, it can be directly on the other layer or substrate, or intervening layers may also be present. Further, it will be understood that when a layer is referred to as being ‘under’ another layer, it can be directly under, and one or more intervening layers may also be present. In addition, it will also be understood that when a layer is referred to as being ‘between’ two layers, it can be the only layer between the two layers, or one or more intervening layers may also be present. Throughout the written description and drawings, like reference numerals refer to like or similar elements.

Moreover, terms such as first, second and third are used to describe various regions and layers in various embodiments of the invention, but the regions and layers are not temporally or sequentially limited by such terms. Rather, these terms are used to distinguish another region or layer. Accordingly, a first region referred to in one embodiment can be referred to as a second region in another embodiment.

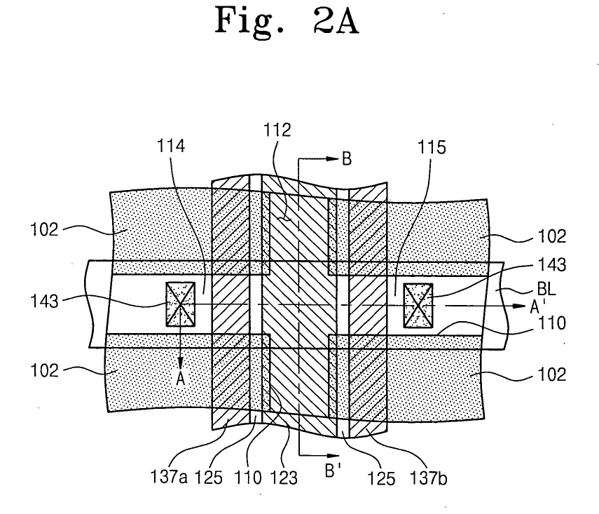

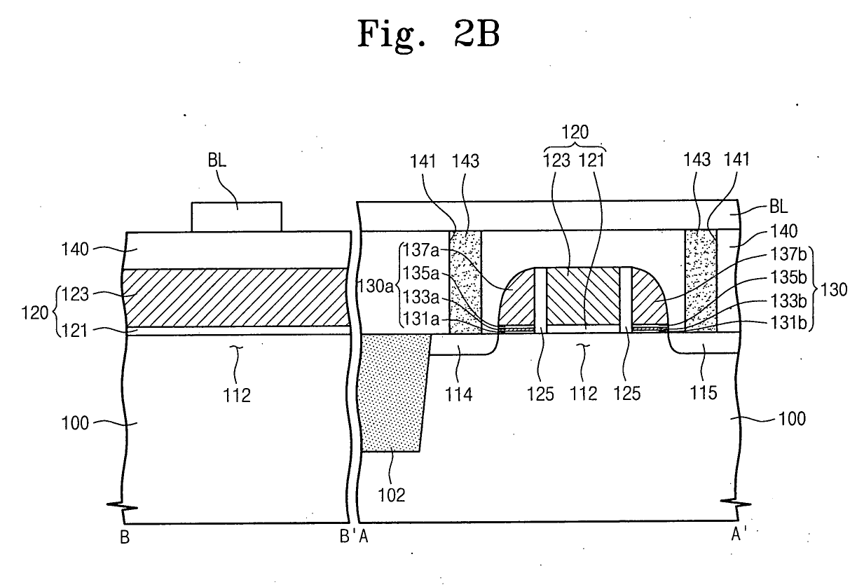

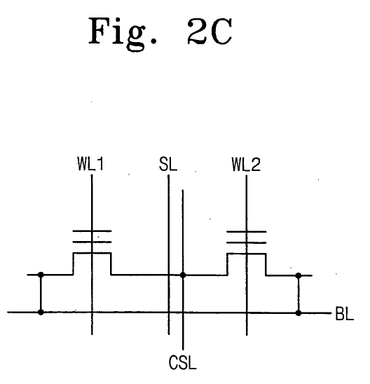

A unit memory cell structure for a non-volatile memory device according to an embodiment of the invention will be described with reference to FIGS. 2A, 2B, and 2C. The non-volatile memory device includes a semiconductor substrate 100 having a device isolation layer 102 defining an active region 110, and memory cell units on the semiconductor substrate 100. The active region 110 may have electrical characteristics defined by a first conductive type (e.g., p-type), and be formed in a cross stripe pattern defined by an island shaped device isolation layer 102. The memory cell units may be arranged on the semiconductor substrate 100 in a matrix of rows and columns. The row direction will be referred to as a first direction, and the column direction will be referred to as second direction crossing the first direction.

Each of the memory cell units includes a common source region 112 on the active region, a select gate 123 covering the common source region 112, a first memory gate 137a on the active region adjacent to one side of the select gate 123, a second memory gate 137b on the active region adjacent to the other side of the select gate 123, and first and second drain regions 114 and 115. The first and second drain regions 114 and 115 are provided in the active region 110 on both sides of a gate structure having the first memory gate 137a, the second memory gate 137b, and the select gate 123. The regions 114 and 115 may include a second conductive type (e.g., n-type) impurity opposite to the first conductive type. The portion of the active region 110 between the drain regions 114 and 115 may be doped with one or more first conductive-type impurities. The drain regions 114 and 115 may be shared by adjacent memory cell units (not shown).

The first and second memory gates 137a and 137b may be a spacer shape provided on the sidewall of the select gate 123. Insulation spacers 125 are interposed between the first and second memory gates 137a and 137b and the select gate 123. The select gate 123 may include polycrystal silicon doped with one or more second conductive-type impurities and a metal silicide layer. The first and second memory gates 137a and 137b may be formed from polysilicon. The insulation spacers 125 may be formed from a chemical vapor deposition (CVD) deposited oxide layer.

A select gate insulation layer 121 is provided between the common source region 112 and the select gate 123. The select gate insulation layer 121 may be formed from a silicon oxide layer deposited by a thermal oxidation process. A first charge storage layer 133a is interposed between the active region 110 and the first memory gate 137a, and a second charge storage layer 133b is interposed between the active region 110 and the second memory gate 137b. Tunnel insulation layers 131a and 131b are interposed between the first charge storage layer 133a and the active region 110, and between the second charge storage layer 133b and the active region 110, respectively. The tunnel insulation layers 131a and 131b may be formed from a silicon oxide layer deposited by a thermal oxidation process. Blocking insulation layers 135a and 135b are interposed between the first memory gate 137a and the first charge storage layer 133a, and between the second memory gate 137b and the second charge storage layer 133b, respectively.

The charge storage layers 133a and 133b may form a charge trap layer, or a floating gate including polysilicon. The charge trap layer may include at least one of a silicon nitride layer, Al2O3, hafnium aluminate, HfAlO, HfAlON, hafnium silicate, HfSiO, or HfSiON. The charge trap layer may include a conducting material formed in dot shape and/or an insulating material. The blocking insulation layers 135a and 135b may have a higher dielectric constant than the tunnel insulation layer to prevent electrons stored in the charge storage layers from being emitted into the memory gates. The blocking insulation layer may include a silicon oxide layer, a silicon nitride layer, Al2O3, hafnium aluminate, HfAlO, HfAlON, hafnium silicate, HfSiO, and/or HfSiON.

Current flowing to the common source region 112 may be turned ON/OFF by a control of the select gate 123. The common source region 112 may be formed from a first conductive-type impurity region. The common source region 112 may have the width narrower or identical to the width in the first direction of the select gate 123.

A first memory cell 130a may include the tunnel insulation layer 131a, the first charge storage layer 133a, the blocking insulation layer 135a, and the first memory gate 137a. A second memory cell 130b may include the tunnel insulation layer 131b, the second charge storage layer 133b, the blocking insulation layer 135b, and the second memory gate 137b. A select cell 120 may include the select gate insulation layer 121 and the select gate 123. The first memory cell, the select cell, and the second memory cell may be separated by the insulation spacers 125.

From the foregoing exemplary description, it may be understood that the non-volatile memory device includes one non-volatile memory transistor having the first and second memory cells, the select cell, and the first and second drain regions, and thus has two memory cells.

The non-volatile memory device further includes an interlayer insulation layer 140 on the semiconductor substrate. Bit line contact plugs 143 penetrate the interlayer insulation layer 140 to connect to the first and second drain regions 114 and 115.

The non-volatile memory device may further include a bit line BL, a select line SL, a common source line CSL, and first and second word lines WL1 and WL2. The bit line BL is provided on the interlayer insulation layer 140 to connect to the bit line contact plugs 143. The bit line BL is commonly connected to the first and second drain regions 114 and 115 and extends in the first direction. The first and second word lines WL1 and WL2 are connected to the first and second memory gates 137a and 137b, respectively, and extend in the second direction crossing over the first direction. The select line SL is connected to the select gate 123 and extends in parallel between the first word line WL1 and the second word line WL2. The common source line CSL is provided by extending the common source region 112 in the second direction, and is covered by the select line SL.

Accordingly, the memory cell unit includes one non-volatile memory transistor, and thus can include two cells. Since one cell unit can include two cells in the non-volatile memory device, a device can be more densely integrated.

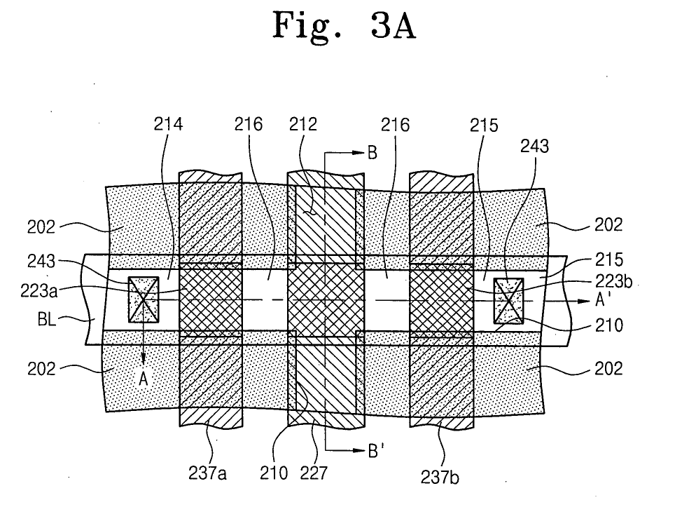

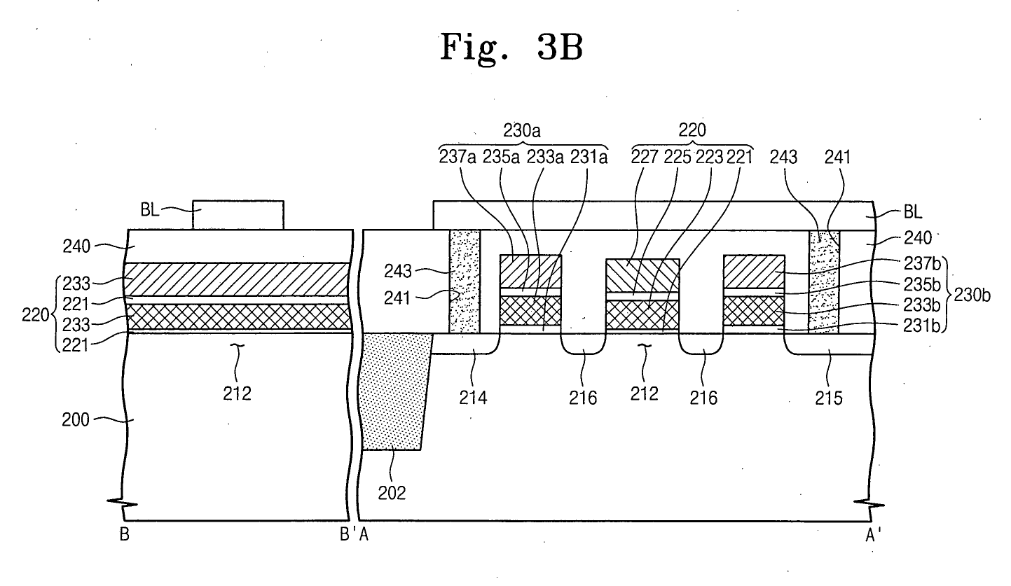

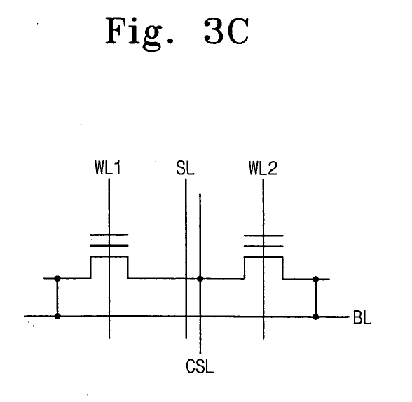

Referring now to FIGS. 3A, 3B, and 3C, a non-volatile memory device will be described according to another embodiment of the present invention. The non-volatile memory device includes a semiconductor substrate 200 having a device isolation layer 202 defining an active region, and memory cell units on the semiconductor substrate 100. The active region 210 may again be of first conductive type and be formed in a cross stripe pattern defined by the island shaped device isolation layer 202. The memory cell units are again arranged on the semiconductor substrate 200 in a matrix of rows and columns.

Each of the memory cell units includes a common source region 212 on the active region, a select gate 223 covering the common source region 212, a first memory gate 237a on the active region adjacent to one side of the select gate 223, a second memory gate 237b on the active region adjacent to the other side of the select gate 223, and first and second drain regions 214 and 215. The first and second drain regions 214 and 215 are provided in the active region 210 on both sides of a gate structure having the first memory gate 237a, the second memory gate 237b, and the select gate 223. The drain regions 214 and 215 may be doped with second conductive type impurities. The select gate 223 may be formed from doped polysilicon of second conductive-type and a metal silicide layer. The first and second memory gates 237a and 237b may include polysilicon.

A select gate insulation layer 221 is provided between the common source region 212 and the select gate 223. The select gate insulation layer 221 may be a silicon oxide layer formed by a thermal oxidation process. A first charge storage layer 233a is interposed between the active region 210 and the first memory gate 237a, and a second charge storage layer 233b is interposed between the active region 210 and the second memory gate 237b. Tunnel insulation layers 231a and 231b are interposed between the first charge storage layer 233a and the active region 110, and between the second charge storage layer 233b and the active region 210, respectively. The tunnel insulation layers 231a and 231b may be a silicon oxide layer formed by a thermal oxidation process. The select gate insulation layer 221 may be thinner than the tunnel insulation layers 231a and 231b. Accordingly, current flowing through the common source regions may be more effectively adjusted.

Blocking insulation layers 235a and 235b are interposed between the first memory gate 237a and the first charge storage layer 233a, and between the second memory gate 237b and the second charge storage layer 233b, respectively. The charge storage layers 233a and 233b may serve as a charge trap layer or a floating gate including polysilicon. The charge trap layer may include at least one of a silicon nitride layer, Al2O3, hafnium aluminate, HfAlO, HfAlON, hafnium silicate, HfSiO, or HfSiON. The charge trap layer may include a conducting material in a dot shape or an insulating material. The blocking insulation layers 235a and 235b may have a higher dielectric constant than the tunnel insulation layer to prevent electrons stored in the charge storage layers from being emitted into the memory gates. The blocking insulation layer 235a and 235b may include a silicon oxide layer, a silicon nitride layer, Al2O3, hafnium aluminate, HfAlO, HfAlON, hafnium silicate, HfSiO, and/or HfSiON.

In the illustrated example, the floating diffusion regions 216 may be provided in a portion of the respective active regions between the select gate 223 and the first memory gate 237a, and between the select gate 223 and the second memory gate 237b. The floating diffusion regions 216 may be second conductive type. The floating diffusion regions 216 contact the common source region 212 and can be separated by the common source region 212.

A first memory cell 230a may include the tunnel insulation layer 231a, the first charge storage layer 233a, the blocking insulation layer 235a, and the first memory gate 237a. A second memory cell 230b may include the tunnel insulation layer 231b, the second charge storage layer 233b, the blocking insulation layer 235b, and the second memory gate 237b. A select cell 220 may include the select gate insulation layer 221 and the select gate 223.

From the foregoing, it may be understood that the non-volatile memory device includes three non-volatile memory transistors having the first and second memory cells, the select cell, the floating diffusion region, and the first and second drain regions, and thus has two memory cells.

Like the non-volatile memory device described in relation to FIGS. 2A, 2B, and 2C, select lines, common source lines, bit lines, and word lines are similarly connected in the non-volatile memory device illustrated in FIGS. 3A, 3B, and 3C. Since the memory cell unit of these non-volatile memory devices can have two cells, each may be more densely integrated. Additionally, since the select gate insulation layer of the select cell has a smaller thickness than the tunnel insulation layer of the memory cell in the memory cell unit of the non-volatile memory device according to the embodiment of the invention illustrated in FIGS. 3A, 3B and 3C, the current flowing through the common source line may be effectively adjusted.

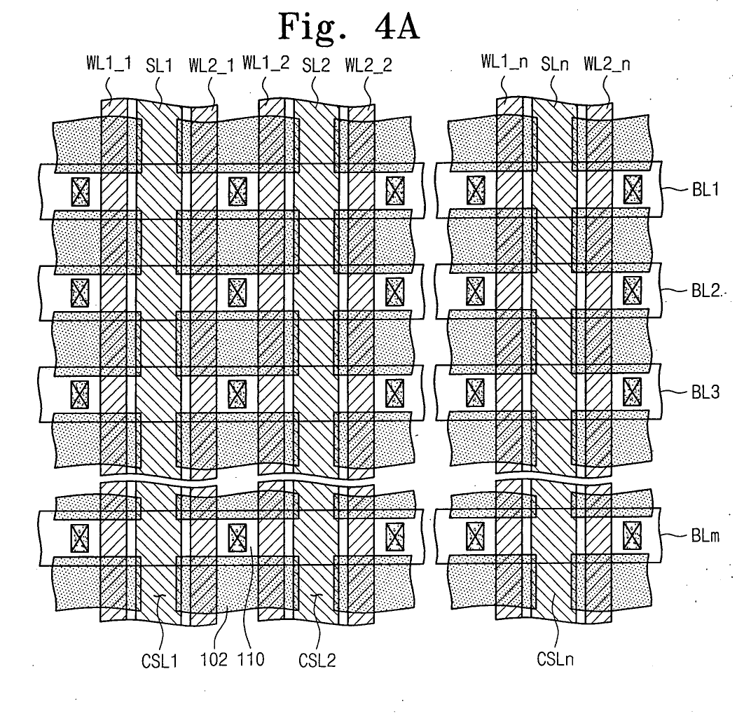

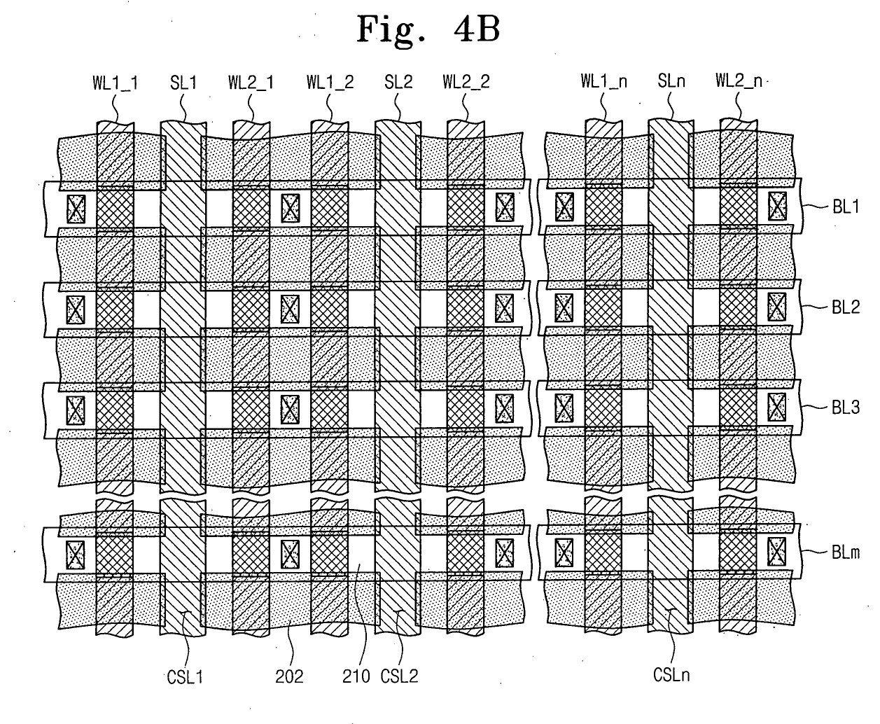

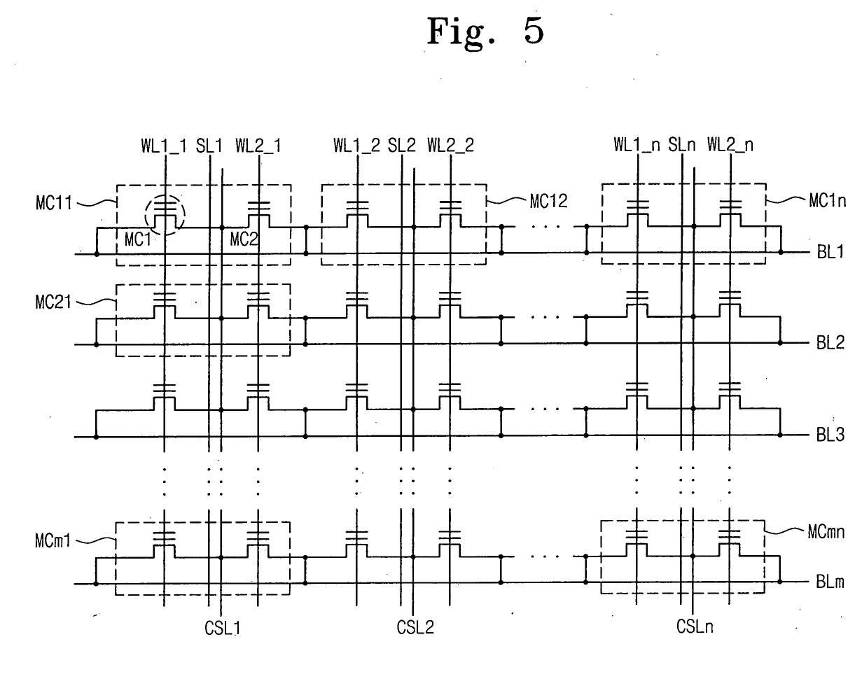

Now, referring to FIGS. 4A, 4B, and 5, respective arrays of a non-volatile memory device will be described in the context of the foregoing embodiments of the present invention. The non-volatile memory device includes a plurality of memory cell units MC11 to MCm1, MC12 to MCm2, . . . MC1n to MCmn in a matrix having a row direction (e.g., the first direction), and a column direction (e.g., the second direction). The semiconductor substrate includes device isolation layers 102 and 202 defining active regions 110 and 210 of first conductive-type. The respective active regions are formed in a cross stripe pattern defined by the respective island shaped device isolation layers. The plurality of memory cell units are provided on the active regions. The structure of the memory cell unit will be described with reference to FIGS. 2A through 2C, or FIGS. 3A through 3C. In these examples, the bit lines, select lines, common source lines, and first and second word lines are formed in respective pluralities.

The plurality of first word lines WL1_1 to WL1_n and second word lines WL2_1 to WL2_n cross over the active regions 110 and 210 to extend in the second direction. The memory gates arranged in the same columns are electrically connected to the same word lines WL. The first and second word lines are connected to the first memory gate and the second memory gate, respectively. A charge storing region may be provided on regions where the active region and the word lines intersect.

The plurality of bit lines BL1 to BLm intersect the word lines to cover the active regions and extend in the first direction. The bit lines are commonly connected to the first and second drain regions arranged in the same row.

The plurality of common source lines CSL1 to CSLn are provided by extending each common source region between the first word line and the second word line in the second direction. The plurality of select lines SL1 to SLn extend between the first word line and the second word line in parallel with the word lines. For example, the select line SL1 is provided on the active region between the first word line WL1_1 and the second word line WL2_1. The select lines are connected to the select gate. The plurality of select lines SL1 to SLn cover the plurality of common source line CSL1 to CSLn, respectively.

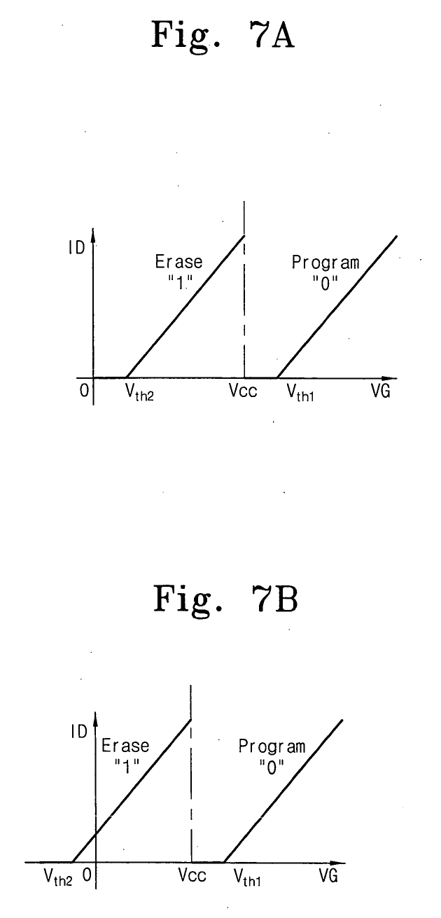

Referring to FIGS. 5, 6A through 6D, 7A, and 7B, a method of driving non-volatile memory devices according to embodiments of the invention will be described. A programming operation for the non-volatile memory transistors within the non-volatile memory device according to embodiments of the present invention is accomplished using Fouler-Nodheim (F-N) tunneling. As illustrative examples, programming, erase, and read operations applied to a first memory cell MC1 of a selected memory cell unit MC11, as shown in FIG. 5 will be described.

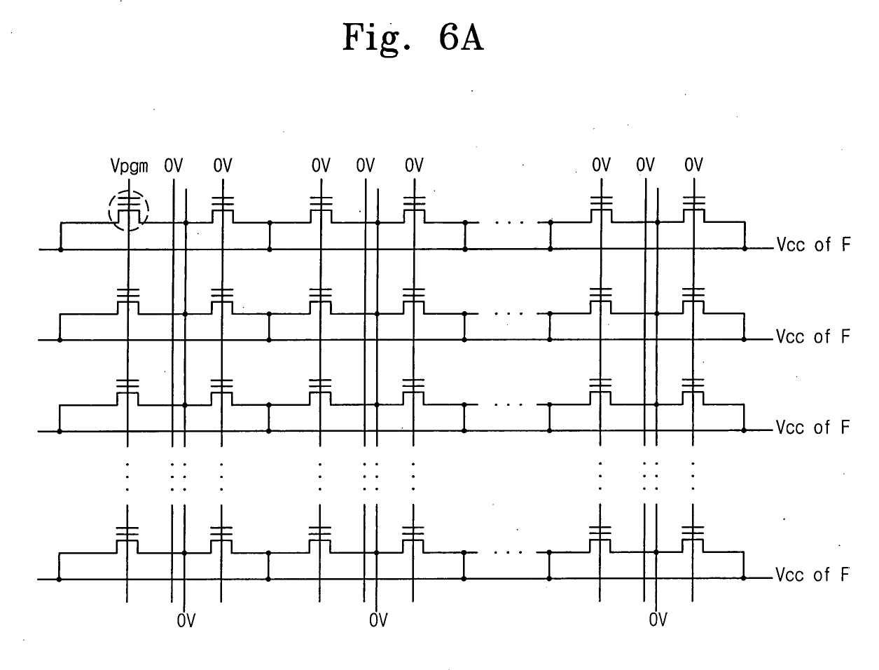

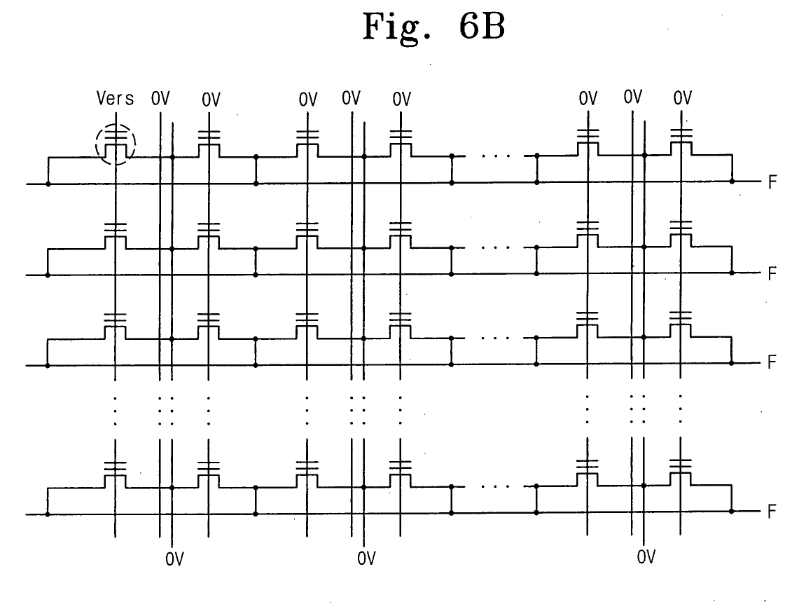

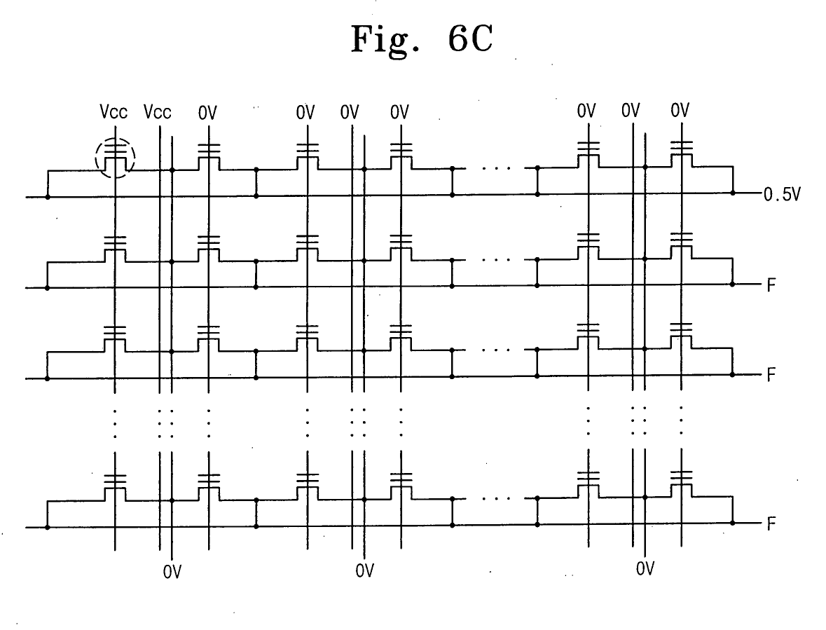

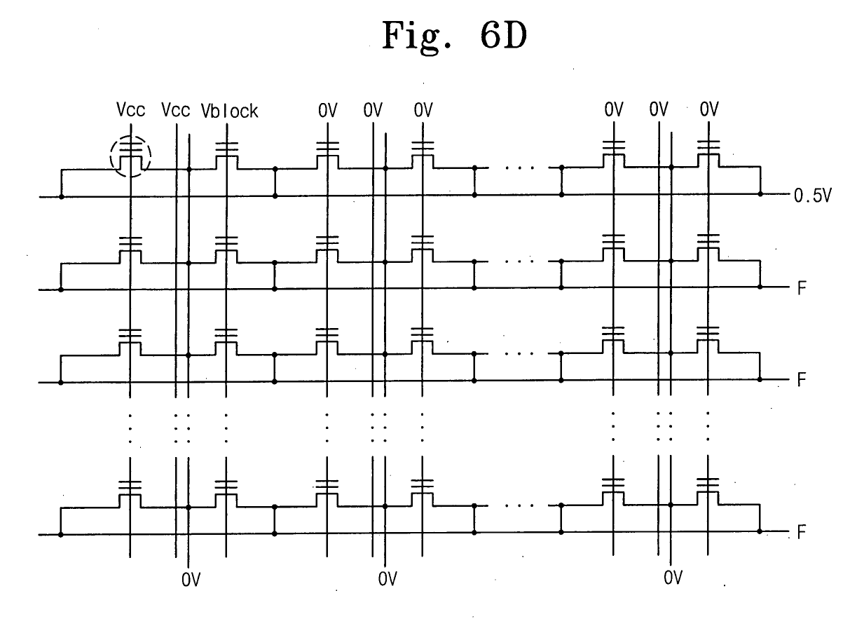

Referring now to FIGS. 5 and 6, a programming operation applied to the first memory cell MC1 of the selected memory cell unit MC11 will be described. A program voltage Vpgm may be applied to the first word line WL1_1 of the selected memory cell unit MC11, and a ground voltage may be applied to the second word line WL2_1 of the selected memory cell unit MC11. Accordingly, the program voltage and the ground voltage may be applied to the first memory gate of the first memory cell MC1 and the second memory gate of the second memory cell MC2, respectively. The select line SL_1, the bit line BL1, and the common source line CSL1 of the selected memory cell unit MC11, and the semiconductor substrate may be grounded. Accordingly, the select gate, the drain regions, and the common source of the cell unit MC11 and the semiconductor substrate may be grounded. First word lines WL1_l, second word lines WL1_l, select lines SLl, and common source lines CSLl of the unselected memory cell unit may be grounded. Bit lines BLk of the unselected memory cell unit may be floating F, or a power voltage Vcc may be applied to the bit line BLk. At this point, 1<k≦m, 1<l≦n.

Accordingly, electrons are injected into a charge storage layer of the first memory cell MC1 in the selected memory cell unit MC11 by the F-N tunneling. The first memory cell MC1 may have a first threshold voltage Vth1. The program voltage Vpgm may be, for example, 15 to 20V, and the power voltage Vcc, 1.8 to 2.3 V.

Referring to FIGS. 5 and 6B, an erase operation applied to the first memory cell MC1 of the selected memory cell unit MC11 will be described. An erasing voltage Vers may be applied into the first word line WL1_1 connected to the first memory cell MC1. Accordingly, an erasing voltage can be applied to the first memory gate of the first memory cell MC1 in the selected memory cell unit MC11. The bit lines BL1 to BLm may be all floating F. Accordingly, the drain regions can float. The common source lines WL2_1 to WLk_l except for the first word line WL1_1, the select lines SL1 to SLn, the common source lines CSL1 to CSLn, and the semiconductor substrate may be grounded. At this point, 1≦k≦m, 1<l≦n. Accordingly, the second memory gate, the select gates, the common source regions, and the semiconductor substrate of the second memory cell MC2 in the selected memory cell unit MC11 can be grounded.

Accordingly, electrons stored in the charge storage layer of the first memory cell MC1 may be emitted into the semiconductor substrate. The first memory cells MC1 connected to the first word line WL1_1 in the column direction may have a second threshold voltage Vth2 lower than the first threshold voltage. The memory cells connected to the first word line WL1_1 are erased collectively. The erasing voltage Vers may be, for example, −15 to −20 V.

Referring now to FIGS. 5, 6C, 6D, 7A, and 7B, a read operation applied to the first memory cell MC1 in the selected memory cell unit MC11 will be described.

Of preliminary note, however, the memory cells of non-volatile memory devices consistent with embodiments of the present invention may use various voltage distributions to define programming and erase states. In the following a particular case where threshold voltages for programmed and erased states are positive will first be assumed. Namely, a first threshold voltage Vth1 associated with a programmed state ranging between 3 to 4 V, and a second threshold voltage Vth2 associated with an erased state of about 0.7 V will be assumed.

A read voltage Vread may be applied to the bit line BL1 of the selected memory cell unit MC11. Accordingly, the read voltage Vread may be applied to the drain regions of the selected memory cell unit MC11. A power voltage Vcc may be applied to the first word line WL1_1 and the select line SL1 of the selected memory cell unit MC11. Accordingly, a power voltage Vcc may be applied to the first memory gate and the select gate of the first memory cell MC1 in the selected memory cell unit MC11. The power voltage Vcc may be different in the first memory gate and the select gate. The second word line WL2_1, the common source line CSL1 of the selected memory cell unit MC11, and the semiconductor substrate may be grounded. The first word line WL1_l, the second word line WL2_l, the select line SLl, and the common source line CSLl of the unselected memory cell units may be grounded. Accordingly, the ground voltage may be applied to the second memory gate, the common source region, and the semiconductor substrate of the second memory cell MC2 in the selected memory cell unit MC11. The bit line BLk of the unselected memory cell unit may floating F. At this point, 1<k≦m, 1<l≦n.

By the power voltage applied to the select line SL1, the common source line CSL1, i.e., a channel of the select cell in the selected memory unit MC11, may be turned on. By the ground voltage applied to the second word line WL2_1, the unselected memory cell in the selected memory cell unit may be turned off. Accordingly, only the selected memory cell may be used for reading operation. The read voltage Vread and the power voltage Vcc may be 0.5 V and 1.8 to 2 V, respectively.

Referring now to FIGS. 5, 6D, and 7B, a case where threshold voltages associated with the programmed and erase states are positive or negative, respectively, will now be described. For example, a first threshold voltage associated with the programmed state may be positive, and a second threshold voltage associated with the erased state may be negative. Namely, the first threshold voltage Vth1 may range from between 2 to 3 V, and the second threshold voltage Vth2 may range from between −1 to 0 V in the illustrated example.

A read voltage Vread is applied to the bit line BL1 of the selected memory cell unit MC11. Accordingly, a read voltage may be applied to the drain regions of the selected memory cell unit MC11. A read blocking voltage Vblock may be applied to the second word line WL2_1 of the selected memory cell unit MC11. Accordingly, the read blocking voltage may be applied to the second memory gate of the second memory cell MC2 in the selected memory cell unit MC11. A power voltage Vccc may be applied to the first word line WL1_1 and the select line SL1 of the selected memory cell unit MC11. Accordingly, the power voltage may be applied to the first memory gate and the select gate of the first memory cell MC1 in the selected memory cell unit MC11. The power voltage Vcc may be different in the first memory gate and the select gate. The common source line CLS1 of the selected memory cell unit MC11 and the semiconductor substrate may be grounded. Accordingly, the common source region and the semiconductor substrate of the selected memory cell unit MC11 are grounded. The first word lines WL1_l, the second word lines WL2_l, the select lines SL1 to SLn and the common source lines CSL1 to CLSn in the unselected memory cell units MCkl may be grounded. The bit line BLk of the unselected memory cell unit may floating F. At this point, 1<k≦m, 1<l≦n.

The read blocking voltage Vblock prevents a current flowing into the unselected memories connected to the same select line, thereby inhibiting malfunction of the device. The read blocking voltage Vblock may be negative. By a power voltage applied to the select line SL1, the common source line CSL1, i.e., a channel of the select cell in the selected memory unit MC11, may be turned on. Accordingly, only the selected memory cells may be used for reading operation when the unselected memory cell of the selected memory cell unit is turned off. The read voltage Vread, the read blocking voltage Vblock and the power voltage Vcc may be 0.5 V and −1.8 to −2.3 V, and 1.8 to 2 V, respectively.

FIGS. 2A, 2B, 8A, 8B, 9A, and 9B, methods of fabricating a non-volatile memory device will be described according to an embodiment of the present invention.

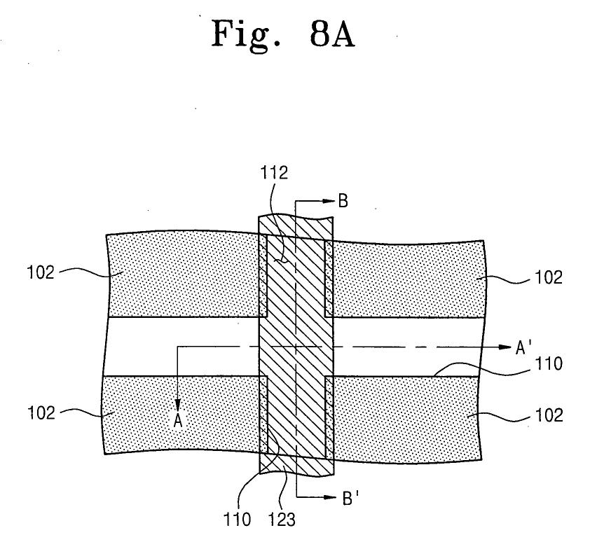

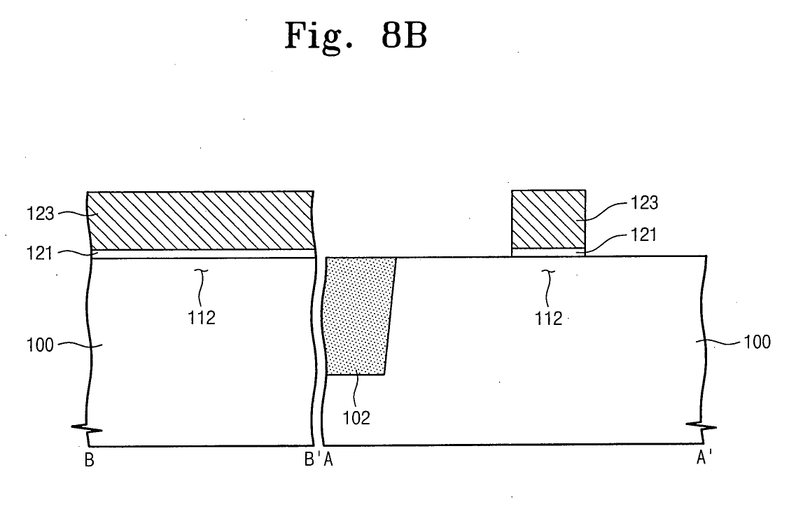

Referring to FIGS. 8A and 8B, a first conductive type, (e.g., p-type), semiconductor substrate 100 is provided. An island shaped device isolation layer 102 is formed in the semiconductor substrate 100. An active region 110 is thus defined by the device isolation layer 102 extending in both first and second directions to form a cross stripe pattern. The active region extending in the second direction may be a common source region 112. A select gate insulation layer 121 is formed on the active region. The select gate insulation layer may be a silicon oxide layer formed by a thermal oxidation process. A select gate 123 covering the common source region is formed on the select gate insulation layer. The formation of the select gate 123 may include forming a polysilicon layer on the select gate insulation layer, and patterning the polysilicon layer to form a polysilicon pattern covering the common source region 112. During the patterning, the select gate insulation layer 121 may be also patterned such that it remains only below the select gate 123. The select gate 123 may have a greater width than the common source region 112.

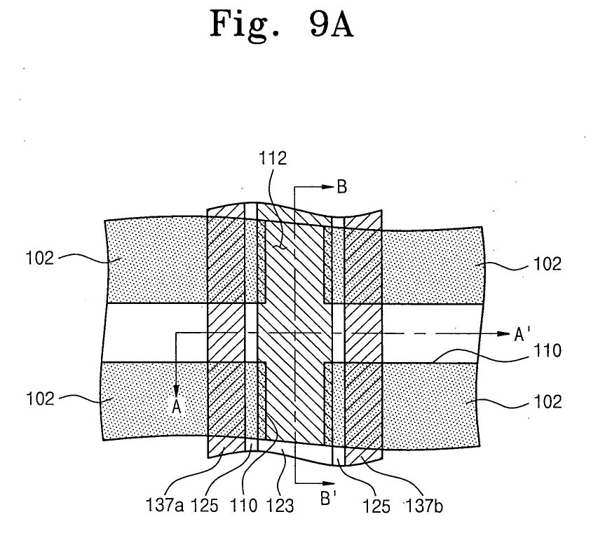

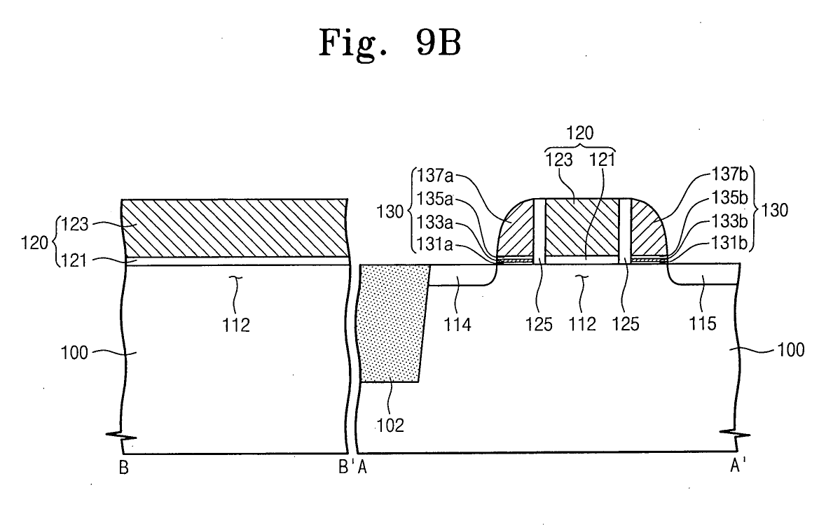

Referring to FIGS. 9A and 9B, insulation spacers 125 are formed on a sidewall of the select gate 123. The forming of the insulation spacers may include forming a chemical vapor deposition (CVD) oxide layer, and performing an anisotropy etching process. The insulation spacers 125 may have a thickness adapted to prevent disturbance that is caused by a voltage difference between the select gate and the first and second memory gates. First and second memory cells 130a and 130b are formed on the both sides of the select gate 123 by interposing the insulation spacers 125.

The formation of the first and second memory cells 130a and 130b may be achieved by a following exemplary process. A tunnel insulation layer is formed on the semiconductor substrate 100 adjacent to both sides of the select gate 123. The tunnel insulation layer may be formed from a silicon oxide layer formed by a thermal oxidation process on the semiconductor substrate 100. The tunnel insulation layer may be formed to a thickness ranging from about 50 to 120 Å. Additionally, the tunnel insulation layer includes a hafnium oxide layer or an aluminum oxide layer. The tunnel insulation layers may be formed using a thermal oxidation process, an atomic layer deposition process, or a CVD process. A charge storage layer and a blocking insulation layer may be formed sequentially. The charge storage layer and the blocking insulation layer may be formed on the tunnel insulation layer adjacent to the insulation spacers 125, and may conformally cover the top and the sidewall of the insulation spacers 125 and the select gate 123 simultaneously. The charge storage layer may be a floating gate including a charge trap layer or a polysilicon. The charge trap layer may include at least one of a silicon nitride layer, Al2O3, hafnium aluminate, HfAlO, HfAlON, hafnium silicate, HfSiO, or HfSiON. The charge trap layer may include a conducting material formed in a dot shape and/or an insulating material. The blocking insulation layer may have a higher dielectric constant than the tunnel insulation layer. The blocking insulation layer may include a silicon oxide layer, a silicon nitride layer, Al2O3, hafnium aluminate, HfAlO, HfAlON, hafnium silicate, HfSiO, and/or HfSiON. A conductive layer may be formed on the blocking insulation layer. The conductive layer may include polysilicon layer doped with the second conductive-type impurity ion, or a polysilicon layer and a metal silicide layer. An anisotropy etching process may be performed on the conductive layer.

Accordingly, first and second memory gates 137a and 137b may be formed on the both sides of the select gate 123 by interposing the insulation spacers 125. The first and second memory gates 137a and 137b may be in a spacer shape. By performing the anisotropy etching process on the conductive layer, the charge storage layer and the blocking insulation layer on the select gate 123 may be removed. The charge storage layer and the blocking insulation layer may remain on the sidewalls of the insulation spacers 125, and the remaining charge storage layer and the blocking insulation layer may be some parts of the insulation spacers 125. Accordingly, the insulation spacers 125 may include the remaining charge storage layer and the blocking insulation layer.

First and second drain regions 114 and 115 are formed on the active region at both sides of a gate structure including the first memory gate 137a, the second memory gate 137b, and the select gate. The forming of the drain regions 114 and 115 may include implanting a second conductive type (n-type) opposite to the first conductive type. During the forming of the drain regions 114 and 115, since active regions between the drain regions 114 and 115 are covered by the first and second memory gates 137a and 137b, the select gate 123, and the insulation spacer 125, the N-type impurity may not be implanted in the active regions between the drain regions. The active regions between the drain regions 114 and 115 may have the first conductive type.

A first memory cell 130a may include the tunnel insulation layer 131a, the first charge storage layer 133a, the blocking insulation layer 135a, and the first memory gate 137a. A second memory cell 139b may include the tunnel insulation layer 131b, the second charge storage layer 133b, the blocking insulation layer 135b, and the second memory gate 137b. A select cell may include the select gate insulation layer 121 and the select gate 123.

Referring to FIGS. 2A and 2B again, an interlayer insulation layer 140 is formed to cover the select gate 123 and the memory gates 137a and 137b. Contact holes are formed to expose the drain regions 114 and 115, and a contact plug material is filled in the contact holes 141. The contact plug material may be tungsten. The filled contact plugs form bit line contact plugs 143. A metal conductive layer is formed on the interlayer insulation layer 140 and then patterned to form a bit line BL connected to the bit line contact plugs 143. The bit line BL is shared by the drain regions 114 and 115.

Referring to FIGS. 3A, 3B, 10A through 13A, and 10B through 13B, a method of forming a non-volatile memory device will be described according to an embodiment of the present invention.

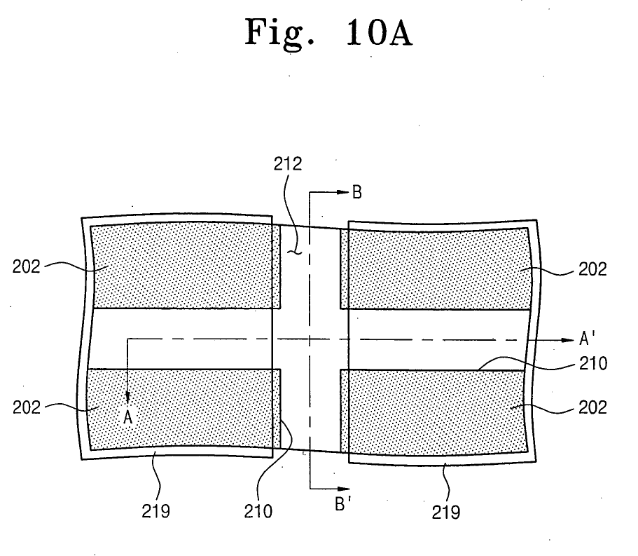

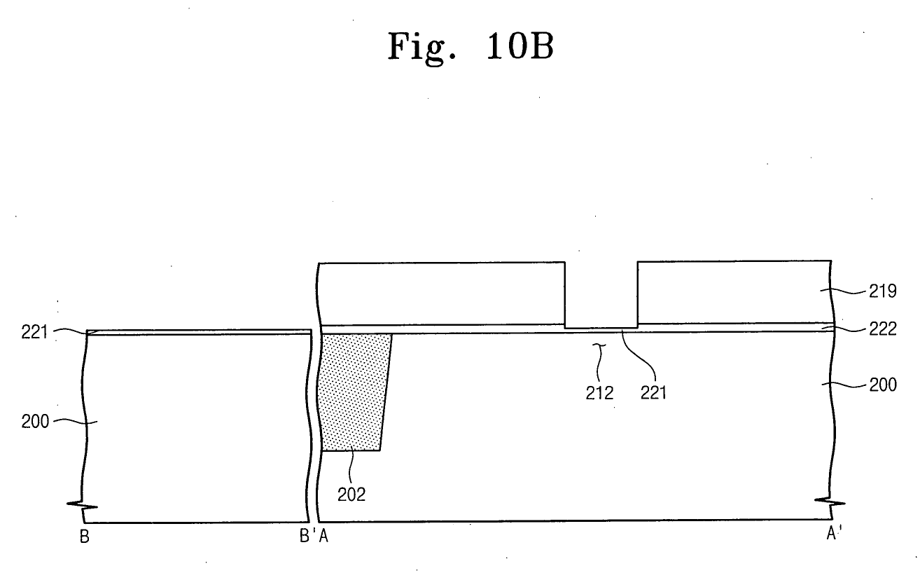

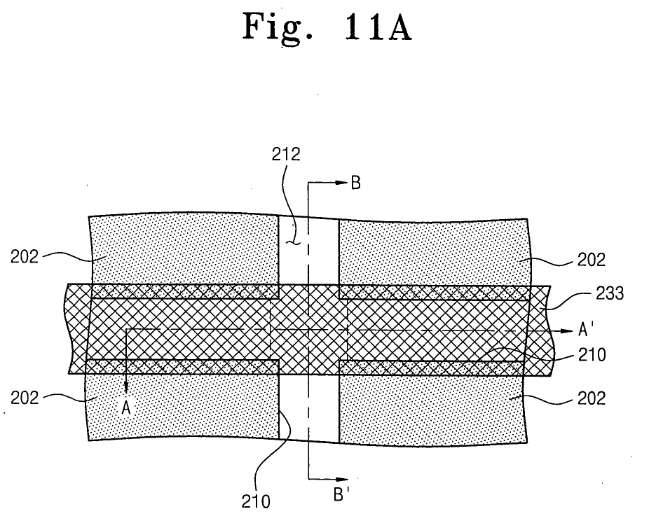

Referring to FIGS. 10A and 10B, a first conductive type (p-type), semiconductor substrate 200 is provided. An island shaped device isolation layer 202 may be formed in semiconductor substrate 200. An active region 210 defined by the device isolation layer 202 again extends in the first and second direction in a cross stripe pattern. The active region extending in the second direction may be a common source region 112. A gate insulation layer 222 having a first thickness may be formed on the active region. The gate insulation layer 222 may be a silicon oxide layer formed by a thermal oxidation. A first mask pattern 219 may be formed on the gate insulation layer 222. The first mask pattern may be a photoresist. The first mask pattern may have openings exposing the common source region 212. The opening may have a greater width then the common source region 212. The gate insulation layer is recessed by using the first mask pattern as an etching mask such that the gate insulation layer on the common source region 212 may have a second thickness thinner than that of the first thickness. The gate insulation layer having the second thickness may be a select gate insulation layer 221.

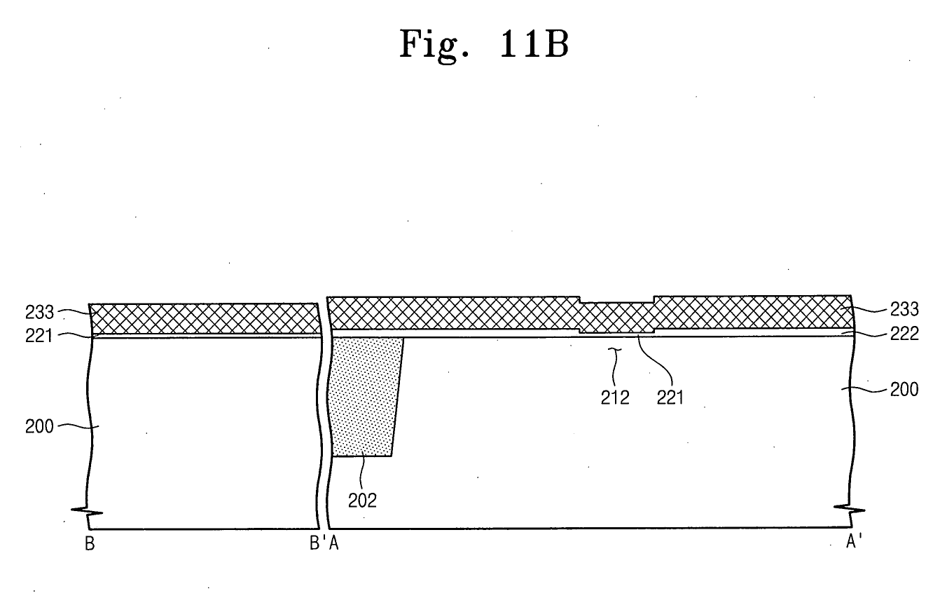

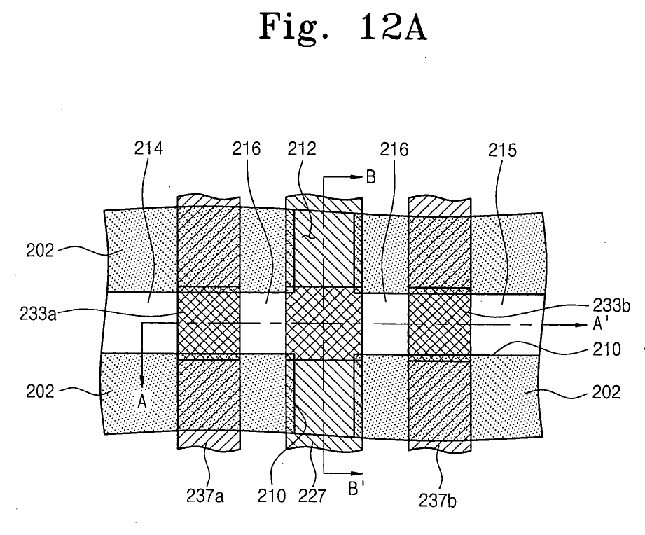

Referring to FIGS. 11A and 11B, a charge storage layer is formed on the select gate insulation layer 221 and the gate insulation layer 222. The charge storage layer may be a charge trap layer or a floating gate including polysilicon. The charge trap layer may include at least one of a silicon nitride layer, Al2O3, hafnium aluminate, HfAlO, HfAlON, hafnium silicate, HfSiO, or HfSiON. The charge trap layer may include a conducting material in a dot shape or an insulating material. By using a mask pattern (not shown), the charge storage layer is patterned to form a charge storing pattern 233 covering the active region extending in the first direction.

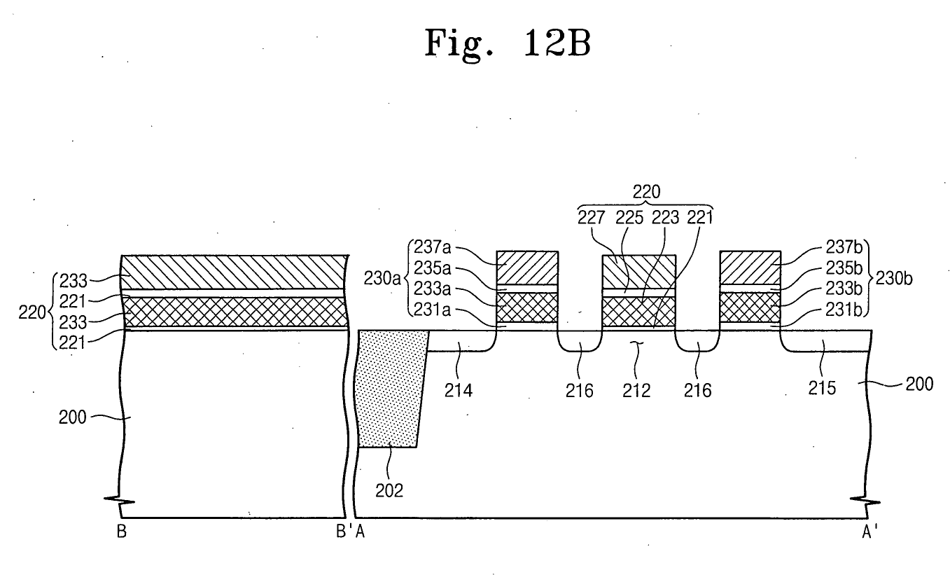

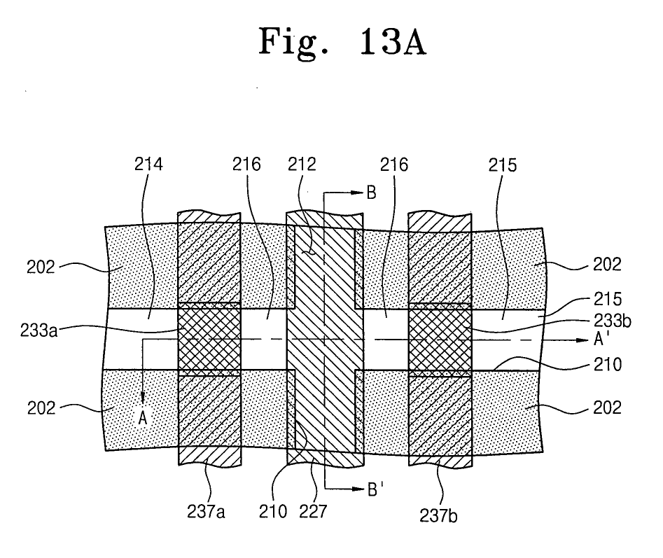

Referring to FIGS. 12A and 12B, a blocking insulation layer is formed on the charge storing pattern 233. The blocking insulation layer may have a higher dielectric constant than the gate insulation layer to prevent electrons stored in the charge storing pattern from being emitted into a memory gate. The blocking insulation layer may include a silicon oxide layer, a silicon nitride layer, Al2O3, hafnium aluminate, HfAlO, HfAlON, hafnium silicate, HfSiO, and/or HfSiON. A conductive layer is formed on the blocking insulation layer. The conductive layer may include polysilicon doped with second conductive-type impurities, or a polysilicon layer and a metal silicide layer.

The conductive layer, the blocking insulation layer, the charge storing pattern 233, the gate insulation layer 222, and the select gate insulation layer are etched by using a mask pattern (not shown) as an etching mask. Formed are a select gate 227 on the common source region 212, a first memory gate 237a on an active region in one side of the common source region 212, and a second memory gate 237b on an active region in the other side of the common source region 212. A select gate insulation layer having the second thickness may be interposed between the common source region 212 and the select gate 227. The charge storing pattern 223 and the blocking insulation layer 225 may be interposed between the select gate 227 and the select gate insulation layer 221. The select gate 227 and the charge storing pattern 223 may be electrically connected to each other. Tunnel insulation layers 231a and 231b having the first thickness may be interposed between the active region 210 and the first and second memory gates 237a and 237b.

By using the select gate 227 and the first and second memory gates 237a and 237b as a mask, the second conductive impurity ion may be implanted on the semiconductor substrate. First and second drain regions 214 and 215 may be provided on the active region on both sides of a gate structure having the first memory gate 237a, the second memory gate 237b, and the select gate 223. Simultaneously, a floating diffusion region 216 may be formed between the select gate 227 and the first memory gate 237a, and between the select gate 227 and the second memory gate 237b.

A first memory cell 230a may include the tunnel insulation layer 231a, the first charge storage layer 233a, the blocking insulation layer 235a, and the first memory gate 237a. A second memory cell 230b may include the tunnel insulation layer 231b, the second charge storage layer 233b, the blocking insulation layer 235b, and the second memory gate 237b. A select cell 220 may include the select gate insulation layer 221 and the select gate 223.

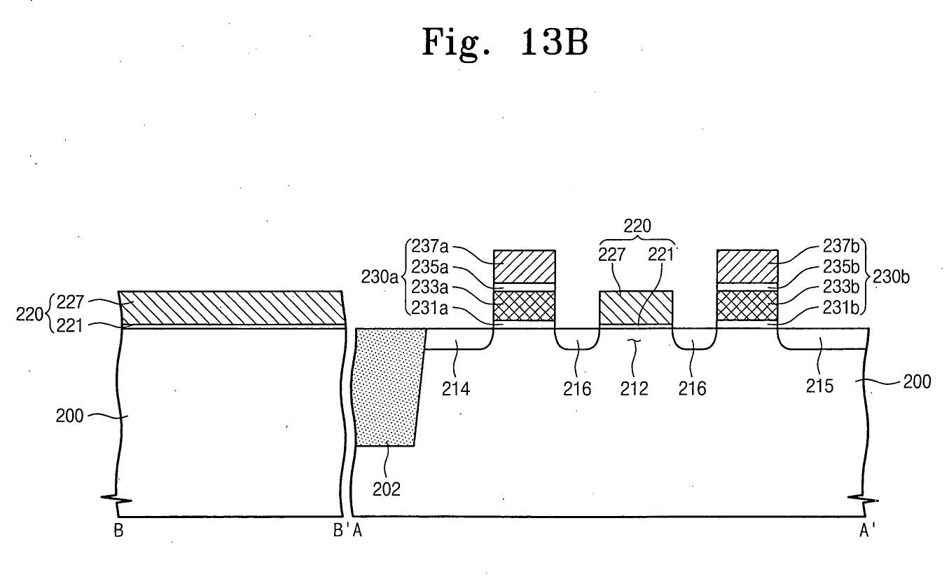

Referring to FIGS. 13A and 13B, unlike FIGS. 12A and 12B, the charge storage layer and the blocking insulation layer on the common source region 212 may be removed before forming the conductive layer. Accordingly, the select gate 227 may contact the select gate insulation layer 221 in the common source region 212. The rest of the components may be similar to those described in relation to FIGS. 12A and 12B.

Referring to FIGS. 3A and 3B, an interlayer insulation layer 240 is formed to cover the select gate and the memory gates. Contact holes are formed to expose the drain regions 214 and 215, and a contact plug material is filled in the contact holes. The contact plug material may be tungsten. The filled contact plugs form bit line contact plugs 243. A metal conductive layer is formed on the interlayer insulation layer 140 and then patterned to form a bit line BL connected to the bit line contact plugs 243. The bit line BL is shared by the drain regions 214 and 215.

According to the present invention, one cell unit includes two cells. Moreover, compared to conventional EEPROM devices, integration density may be improved by overall size reductions on the order of 30 to 40%.

Moreover, since programming and erase operations applied to the constituent memory cell are performed via F-N tunneling, the corresponding programming current may be reduced, and cell endurance improved over conventional NOR flash memory devices.

The above-disclosed subject matter is to be considered illustrative, and not restrictive, and the appended claims are intended to cover modifications, enhancements, and other embodiments, which fall within the scope of the present invention. Thus, to the maximum extent allowed by law, the scope of the present invention is to be determined by the broadest permissible interpretation of the following claims and their equivalents.

What is claimed is:

1. A non-volatile memory device comprising:
a semiconductor substrate having a device isolation layer defining an active region; and
memory cell units arranged on the semiconductor substrate in a matrix having rows and columns, wherein each of the memory cell units comprises:
a common source region disposed in the active region;
a select gate covering the common source region;
a first memory gate on the active region adjacent to one side of the select gate;
a second memory gate on the active region adjacent to the other side of the select gate; and
first and second drain regions in the active region at both sides of a gate structure including the first memory gate, the second memory gate, and the select gate.

2. The non-volatile memory device of claim 1, wherein the active region between the first and second drain regions has a conductivity opposite to that of the first and second drain regions.

3. The non-volatile memory device of claim 1, wherein the first and second memory gates are in a spacer form on a sidewall of the select gate, and each of the memory cell units further comprises insulation spacers between the memory gates and the select gate.

4. The non-volatile memory device of claim 3, wherein each of the memory cell units further comprises first and second charge storage layers between the active region and the memory gates.

5. The non-volatile memory device of claim 4, further comprising:
common source lines including the common source extending in a column direction;
select lines connected to the select gate to extend in the row direction;
first and second word lines connected to the first and second memory gates, respectively, and extending in the column direction; and
bit lines commonly connected to the drain regions arranged in the row direction and extending in the row direction.

6. The non-volatile memory device of claim 5, wherein a programming operation applied to the memory cell units makes use of Fouler-Nordheim tunneling.

7. The non-volatile memory device of claim 6, wherein each of the memory cell units further comprises:
a first memory cell and a second memory cell, the first memory including the first memory gate and the first charge storage layer, the second memory cell including the second memory gate and the second charge storage layer.

8. The non-volatile memory device of claim 7, wherein a programming operation for the first memory cell in selected memory cell unit comprises:
applying a write voltage to a first word line of the selected memory cell unit;
applying a ground voltage to a second word line, a select line, a bit line and a common source line of the selected memory cell unit, the semiconductor substrate, and word lines, select lines, and common source lines of an unselected memory cell unit; and
applying a power voltage to or floating the bit lines of the unselected memory cell unit.

9. The non-volatile memory device of claim 7, wherein an erase operation applied to the first memory cell in selected memory cell unit comprises:
applying an erase voltage to a first word line of the selected memory cell unit;
applying a ground voltage to word lines connected to the memory gates except for the first memory gate, the semiconductor substrate, the select lines, and the common source lines; and
floating the bit lines.

10. The non-volatile memory device of claim 7, wherein respective threshold voltages for the memory cells as the result of both erase and programming operations are positive.

11. The non-volatile memory device of claim 10, wherein a read operation applied to the first memory cell in selected memory cell unit comprises:
applying a read voltage to a bit line of the selected memory cell unit;
applying a power voltage to a first word line and a select line in the selected memory cell unit;
applying a ground voltage to a second word line and a common source line in the selected memory cell unit, the semiconductor, and word lines, select lines, and common source lines in an unselected memory cell unit; and
floating bit lines of the unselected memory cell unit.

12. The non-volatile memory device of claim 7, wherein a negative threshold voltage for the memory cell results from the erase operation, and a positive threshold voltage for the memory cell results from the programming operation.

13. The non-volatile memory device of claim 12, wherein a read operation applied to the first memory cell in selected memory cell unit comprises:
applying a read voltage to a bit line of the selected memory cell unit;
applying a power voltage to a first word line and a select line in the selected memory cell unit;
applying a read blocking voltage to a second word line of the selected memory cell unit;
applying a ground voltage to a common source line in the selected memory cell unit, the semiconductor substrate, and word lines, select lines, and common source lines in an unselected memory cell unit; and
floating bit lines of the unselected memory cell unit.

14. The non-volatile memory device of claim 13, wherein the read blocking voltage is negative.

15. The non-volatile memory device of claim 1, wherein each of the memory cell units further comprises:
a select gate insulation layer between the common source region and the select gate;
floating gates between the memory gates and the active region;
blocking insulation layers between the memory gates and the floating gates; and
tunnel insulation layers between the floating gates and the active region.

16. The non-volatile memory device of claim 15, wherein the select gate insulation layer is thinner than the tunnel insulation layer.

17. The non-volatile memory device of claim 1, wherein a current flowing in the common source region is turned ON/OFF by a control of the select gate.

18. The non-volatile memory device of claim 17, wherein the select gate has a greater width than the common source region, and the common source region has a conductive type opposite to that of the drain regions.

19. A method of forming a non-volatile memory device, the method comprising:
providing a semiconductor substrate having a device isolation layer defining an active region;
forming a select gate covering a common source region in the active region;
forming first and second memory gates in the active region at both sides of the select gate;
forming first and second drain regions in the active region at both sides of a gate structure including the first memory gate, the second memory gate, and the select gate; and
forming a bit line connecting the first and second drain regions commonly.

20. The method of claim 19, further comprising:
forming a select gate insulation layer between the common source region and the select gate; and
forming a tunnel insulation layer, a charge storage layer, and a blocking insulation layer between the active region and the memory gates.

21. The method of claim 20, wherein the select gate insulation layer is thinner than the tunnel insulation layer.

22. The method of claim 19, wherein the forming of the first and second memory gates comprising forming conductive spacers on both sides of the select gate, the conductive spacers being insulated from the select gate by insulation spacers.

23. The method of claim 22, wherein an active region between the drain regions is covered by the first and second memory gates, the select gate, and the insulation spacers during the forming of the drain regions.
